(19) United States
(12) Patent Application Publication
(10) Pub. No.: US 2025/0253277 A1
(43) Pub. Date: Aug. 7, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Hung-Kun Lo, New Taipei City (TW); Wei-Yen Woon, Taoyuan City (TW)

(73) Assignee: Taiwan Semiconductor Manufacturing Company, Ltd., Hsinchu (TW)

(21) Appl. No.: 18/432,031

(22) Filed: Feb. 4, 2024

(51) Int. Cl. H01L 23/00; H01L 23/522

(52) U.S. Cl. CPC H01L 24/29; H01L 23/5226; H01L 24/27; H01L 24/32; H01L 24/83; H01L 2224/27622; H01L 2224/29011; H01L 2224/29186; H01L 2224/32225; H01L 2224/83896

(57) ABSTRACT

A semiconductor device includes a substrate, a routing structure, a device layer and a bonding layer. The routing structure is disposed over the substrate, and includes a plurality of dielectric layer and a plurality of conductive features. The device layer is disposed over the routing structure. The bonding layer is disposed between the substrate and the routing structure, wherein the bonding layer includes a plurality of microchannels.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1F are schematic cross-sectional views of various stages in a method of manufacturing a semiconductor device according to some embodiments.

FIG. 2A and FIG. 2B are respectively a top view of a bonding layer of a semiconductor device according to some embodiments of the disclosure.

FIG. 3A to FIG. 3C are schematic cross-sectional views illustrating a method of forming a bonding layer of a semiconductor device according to some embodiments of the disclosure.

FIG. 4A to FIG. 4B are schematic cross-sectional views illustrating a method of forming a bonding layer of a semiconductor device according to some embodiments of the disclosure.

FIG. 5 is a schematic cross-sectional view of a semiconductor device according to some embodiments of the disclosure.

FIG. 6 illustrates a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or features relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. In another example, two features described as having “substantially the same” dimension and/or “substantially” oriented in a particular direction and/or configuration (e.g., “substantially parallel”) encompasses dimension differences between the two features and/or slight orientation variances of the two features from the exact specified orientation that may arise inherently, but not intentionally, from manufacturing tolerances associated with fabricating the two features. Still further, the present disclosure may repeat reference numerals and/or letters in the various examples. This repetition is for the purpose of simplicity and clarity and does not in itself dictate a relationship between the various embodiments and/or configurations described herein.

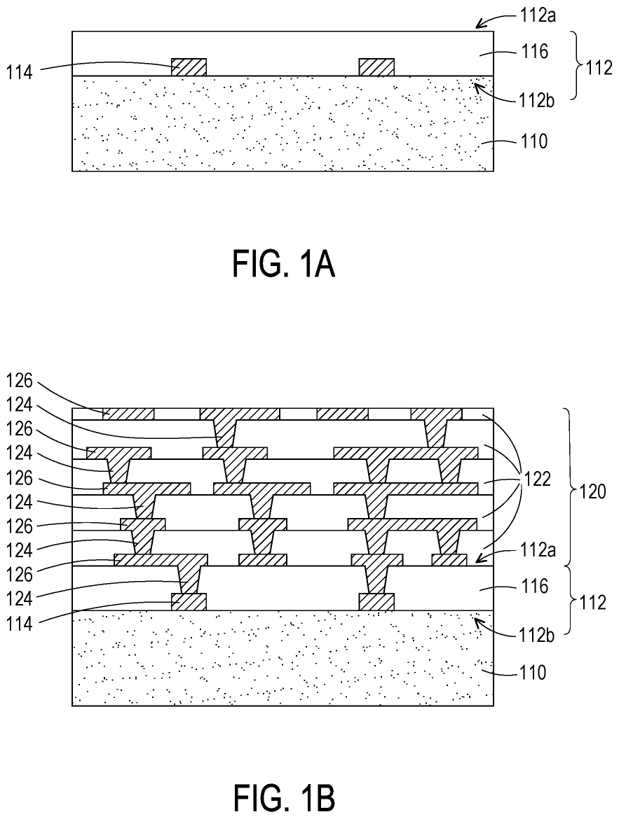

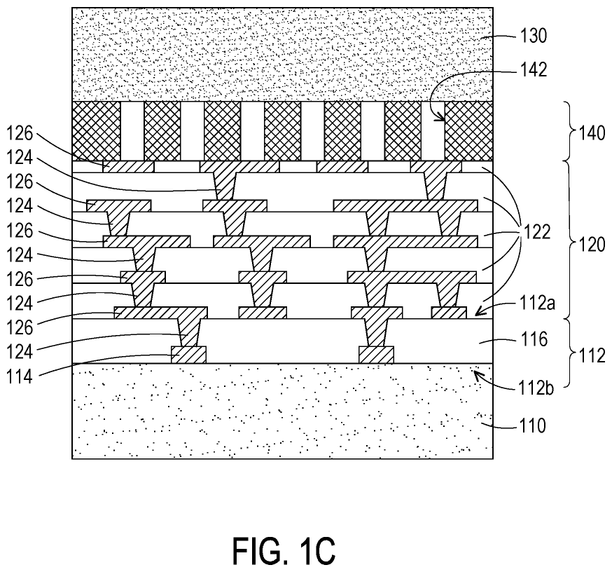

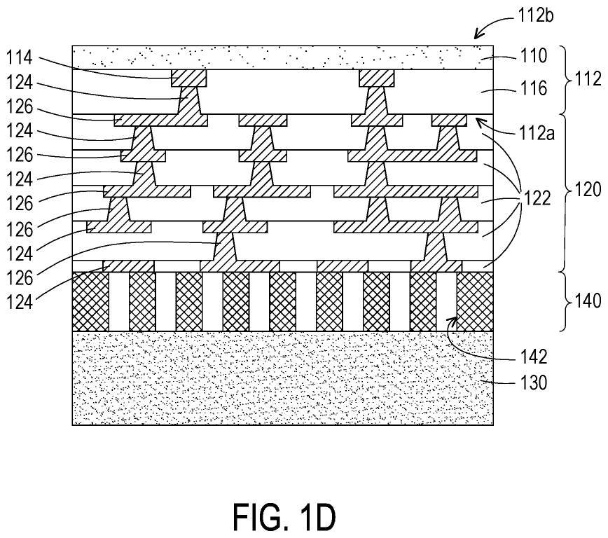

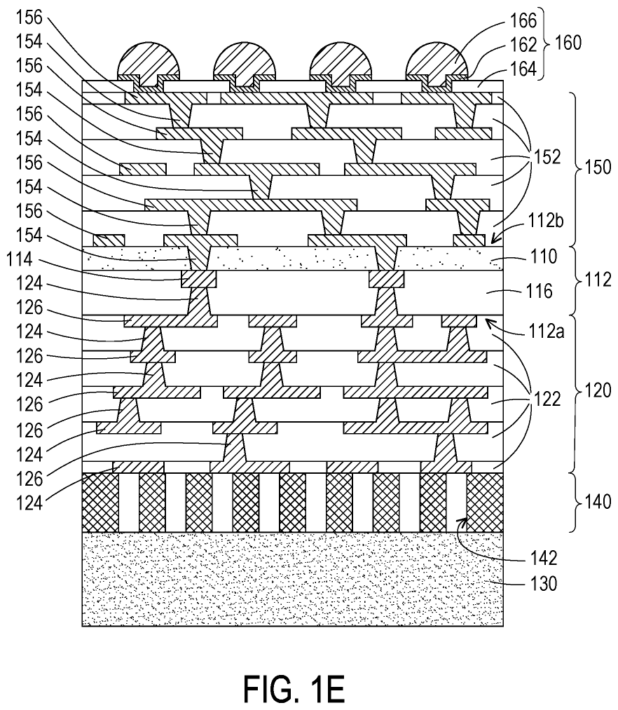

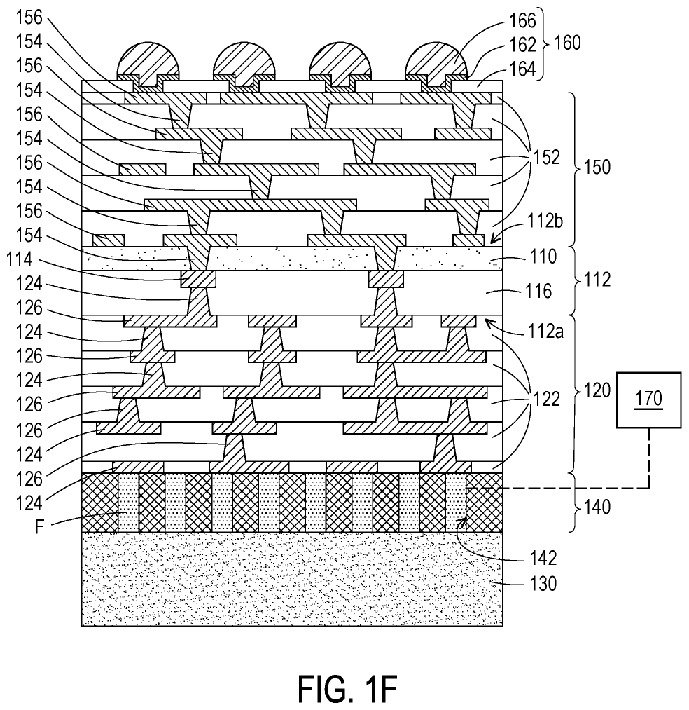

FIG. 1A to FIG. 1F are schematic cross-sectional views of various stages in a method of manufacturing a semiconductor device according to some embodiments.

Referring to FIG. 1A, a substrate 110 is provided. In some embodiments, the substrate 110 is a bulk semiconductor substrate. A “bulk” semiconductor substrate refers to a substrate that is entirely composed of at least one semiconductor material. In some embodiments, the bulk semiconductor substrate includes a semiconductor material or a stack of semiconductor materials such as silicon (Si), germanium (Ge), silicon germanium (SiGe), carbon doped silicon (Si: C), silicon germanium carbon (SiGeC); or an III-V compound semiconductor such as gallium arsenide (GaAs), gallium phosphide (GaP), indium phosphide (InP), indium arsenide (InAs), indium antimonide (InSb), gallium arsenide phosphide (GaAsP), aluminum indium arsenide (AlInAs), aluminum gallium arsenide (AlGaAs), gallium indium arsenide (GaInAs), gallium indium phosphide (GaInP), or gallium indium arsenide phosphide (GaInAsP). In some embodiments, the bulk semiconductor substrate includes a single crystalline semiconductor material such as single crystalline silicon. In some embodiments, the bulk semiconductor substrate is doped depending on design requirements. In some embodiments, the bulk semiconductor substrate is doped with p-type dopants or n-type dopants. The term “p-type” refers to the addition of impurities to an intrinsic semiconductor that creates deficiencies of valence electrons. Exemplary p-type dopants, i.e., p-type impurities, include, but are not limited to, boron, aluminum, gallium, and indium. “n-type” refers to the addition of impurities that contribute free electrons to an intrinsic semiconductor. Exemplary n-type dopants, i.e., n-type impurities, include, but are not limited to, antimony, arsenic, and phosphorous. If doped, the substrate 110, in some embodiments, has a dopant concentration in a range from 1.0×10¹⁴ atoms/cm³ to 1.0×10¹⁷ atoms/cm³, although the dopant concentrations may be greater or smaller. In some embodiments, the substrate 110 is a semiconductor-on-insulator (SOI) substrate including a top semiconductor layer formed on an insulator layer (not shown). The top semiconductor layer includes the above-mentioned semiconductor material such as Si, Ge, SiGe, Si: C, SiGeC; or an III-V compound semiconductor including GaAs, GaP, InP, InAs, InSb, GaAsP, AlInAs, AlGaAs, GaInAs, GaInP, or GaInASP. The insulator layer is, for example, a silicon oxide layer, or the like. The insulator layer is provided over a base substrate, typically a silicon or glass substrate.

Then, a device layer 112 is formed over and/or in the substrate 110. The device layer 112 has a side 112a (e.g., a frontside) and a side 112b (e.g., a backside) that is opposite the side 112a. The device layer 112 may include circuitry fabricated on and/or over the side 112a by front end-of-line (FEOL) processing. For example, the device layer 112 includes various device components/features, such as doped wells (e.g., n-wells and/or p-wells), isolation features (e.g., shallow trench isolation (STI) structures and/or other suitable isolation structures), gate structures (e.g., a metal gate having a gate electrode and a gate dielectric), gate spacers along sidewalls of the gate structure, source/drain features (e.g., epitaxial source/drains), other suitable device components/features, or combinations thereof. The doped wells, the isolation features and the source/drain features may be formed in a portion of the substrate 110. In such embodiments, the device layer 112 includes a portion of the substrate 110. In some embodiments, the device layer 112 includes a planar transistor, where a channel of the planar transistor is formed in the semiconductor substrate between respective source/drains and a respective metal gate is disposed on the channel (e.g., on a portion of the semiconductor substrate in which the channel is formed). In some embodiments, the device layer 102 includes a non-planar transistor having a channel formed in a semiconductor fin that extends from the semiconductor substrate and between respective source/drains on/in the semiconductor fin, where a respective metal gate is disposed on and wraps the channel of the semiconductor fin (i.e., the non-planar transistor is a fin-like field effect transistor (FinFET)). In some embodiments, the device layer 112 includes a non-planar transistor having channels formed in semiconductor layers suspended over the semiconductor substrate and extending between respective source/drains, where a respective metal gate is disposed on and surrounds the channels (i.e., the non-planar transistor is a gate-all-around (GAA) transistor). The various transistors of the device layer 112 can be configured as planar transistors and/or non-planar transistors depending on design requirements.

In some embodiments, the device layer 112 includes a plurality of devices 114. The devices 114 are disposed in a dielectric layer 116, for example. The devices 114 may be passive microelectronic devices and active microelectronic devices, such as resistors, capacitors, inductors, diodes, p-type FETs (PFETs), n-type FETs (NFETs), complementary FETs (CFETs), metal-oxide semiconductor (MOS) FETs (MOSFETs), complementary MOS (CMOS) transistors, bipolar junction transistors (BJTs), laterally diffused MOS (LDMOS) transistors, high voltage transistors, high frequency transistors, other suitable components, or combinations thereof. The devices 114 can be configured to provide functionally distinct regions of an IC, such as a logic region (i.e., a core region), a memory region, an analog region, a peripheral region (e.g., an input/output (I/O) region), a dummy region, other suitable region, or combinations thereof. The logic region may be configured with standard cells, each of which can provide a logic device and/or a logic function, such as an inverter, an AND gate, a NAND gate, an OR gate, an NOR gate, a NOT gate, an XOR gate, an XNOR gate, other suitable logic device, or combinations thereof. The memory region may be configured with memory cells, each of which can provide a storage device and/or storage function, such as flash memory, non-volatile random-access memory (NVRAM), static random-access memory (SRAM), dynamic random-access memory (DRAM), other volatile memory, other non-volatile memory, other suitable memory, or combinations thereof. In some embodiments, memory cells and/or logic cells include transistors and interconnect structures that combine to provide storage devices/functions and logic devices/functions, respectively.

Referring to FIG. 1B, a routing structure 120 is formed over the device layer 112, to electrically connect to the device layer 112. The routing structure 120 is formed on the side 112a (e.g., a frontside) of the device layer 112, and the routing structure 120 may be also referred to as a frontside multilayer interconnect (FMLI) structure. In some embodiments, the routing structure 120 includes a plurality of dielectric layers 122 and a plurality of conductive features (e.g., conductive vias 124, conductive lines 126 and/or contacts) in the dielectric layers 122. The conductive vias 124 and the conductive lines 126 may include a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), a metal three interconnect layer (M3 level), and all the way to a via x interconnect layer (Vx level), and a metal x interconnect layer (Mx level), in which x represents an integer (e.g., from 2 to 10).

Each of the V0 level, M0 level, V1 level, M1 level, V2 Level, M2 level, V3 level, M3 level, . . . . Vx level, and Mx level may be referred to as a metal level. The conductive lines 126 formed at the M0 level may be referred to as M0 metal lines. Similarly, conductive via or conductive lines formed at the V1 level, M1 level, V2 level, M2 level, V3 level, M3 level, . . . . Vx level, and Mx level may be referred to as V1 vias, M1 metal lines, V2 vias, M2 metal lines, V3 vias, M3 metal lines, . . . . Vx vias, Mx metal lines, respectively. In some embodiments, the conductive features at a same level of the routing structure 120, such as M0 level, are formed simultaneously. In some embodiments, conductive features at a same level of the routing structure 120 have top surfaces that are substantially planar with one another and/or bottom surfaces that are substantially planar with one another. In some embodiments, the conductive via 124 of the routing structure 120 has an inclined sidewall, and a width of the conductive via 124 decreases as the conductive via 124 becomes closer to the device layer 112. However, the disclosure is not limited thereto. The conductive via 124 may have a vertical sidewall or substantially vertical sidewall.

The dielectric layer 122 may be also referred to as an interlayer dielectric (ILD) layer. The dielectric layers 122 of the routing structure 120 may be collectively referred to as a dielectric structure. In some embodiments, the dielectric layer 122 includes a low-k dielectric material having a dielectric constant (k) less than 4. In some embodiments, the low-k dielectric material has a dielectric constant from about 1.2 to about 3.5. In some embodiments, the dielectric layer 122 include silicon oxide, TEOS formed oxide, undoped silicate glass, or doped silicate glass such as BPSG, FSG, PSG, BSG, and/or other suitable dielectric materials. In some embodiments, the dielectric layer 122 is deposited by CVD, PECVD, PVD, spin coating, the like, or a combination thereof. An etch stop layer (ESL) may be further disposed below the dielectric layer 122, respectively. The ESL may include a dielectric material, such as, silicon nitride, silicon oxide, silicon oxynitride, or the like, having a different etch rate than the material of the overlying dielectric layer 122.

In some embodiments, the conductive features are formed using a damascene process or a dual-damascene process. For example, a respective dielectric layer 122 is patterned utilizing a combination of photolithography and etching techniques to form openings corresponding to the desired pattern of the conductive features. Then, a conductive material is formed to fill the openings defined in the dielectric layer 122. An optional diffusion barrier layer and/or optional adhesion layer may be deposited in the openings before filled with the conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, combinations thereof, or the like. A chemical mechanical planarization (CMP) process or the like may be used to remove excess conductive material, so as to form the conductive features. In some embodiments, the conductive via 124 and/or the conductive line 126 are in contact with the underlying conductive features such as the conductive via 124 and/or the conductive line 126 in the routing structure 120 and/or conductive features (such as gate structures and/or source/drain features) in the devices 114. The conductive features may be formed by electroplating, deposition, the like or a combination thereof.

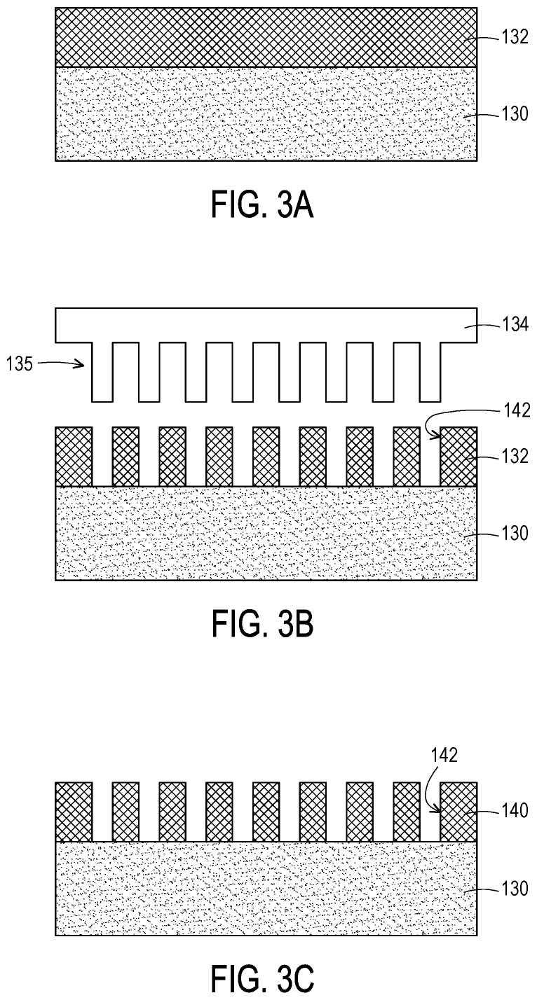

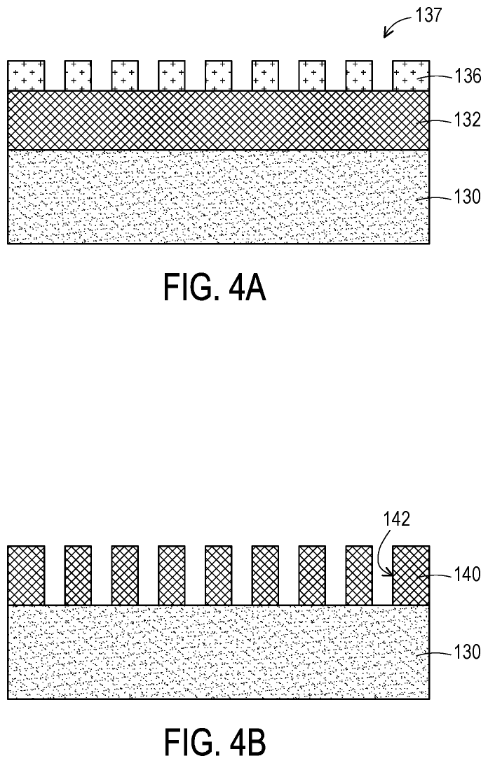

Referring to FIG. 1C, the structure of FIG. 1B is attached to a substrate 130 through a bonding layer 140 having microchannels 142. The substrate 130 may be a wafer carrier (e.g., a silicon wafer), a glass carrier, a ceramic carrier or the like. The substrate 130 may provide structural support during subsequent processing steps and in the completed device. The bonding layer 140 may be bonded to the structure of FIG. 1B with any suitable attaching processes, such as direct bonding, hybrid bonding or other bonding methods. The bonding process may further include alignment, annealing, and/or other processes. The microchannels 142 are formed in the bonding layer 140 before the bonding process. In some embodiments, the bonding layer 140 having the microchannels 142 therein may be formed by the process depicted in FIG. 3A to FIG. 3C or FIG. 4A to FIG. 4B.

In some embodiments, referring to FIG. 3A, a bonding material 132 is formed on the substrate 130. The bonding material 132 includes silicon oxide, silicon nitride, SiCN, SiOCN, and the bonding material 132 is formed by CVD, ALD, PVD, thermal oxidation, or the like, for example. A thickness of the bonding material 132 is in a range of 5 to 10 nm.

Referring to FIG. 3B, by using a transfer element 134 having a pattern 135 complementary to the microchannels 142, a printing process is performed to the bonding material 132. Thus, the microchannels 142 are formed in the bonding material 132. In some embodiments, the printing process is a nano-printing process or a microprinting process. A depth of the microchannels 142 is corresponding to a height of the pattern 135. In some embodiments, a depth of the microchannels 142 is substantially equal to a thickness of the bonding material 132 (also the bonding layer 140 to be formed) in a range of 5 to 10 nm.

Referring to FIG. 3C, a curing process is performed on the bonding material 132 having the microchannels 142 therein, and the bonding layer 140 with the microchannels 142 therein is formed. In some embodiments, the temperature of the curing process is in a range of 5 to 10 nm.

In some embodiments, referring to FIG. 4A, a bonding material 132 is formed on the substrate 130. The material and formation method of the bonding material 132 are similar to those described with reference to FIG. 3A, so the detailed descriptions thereof are omitted herein. Then, a patterned photoresist 136 having a pattern of microchannels 137 is formed on the bonding material 132, for example. The patterned photoresist 136 may be formed by coating a photoresist on the bonding material 132, curing the photoresist and developing the photoresist.

Referring to FIG. 4B, by using the patterned photoresist 136 as a mask, the bonding material 132 is patterned to form a bonding layer 140 with microchannels 142. The patterning process may include an etch process such as a dry etch or a wet etch. After that, the patterned photoresist 136 is removed by a stripping process, for example.

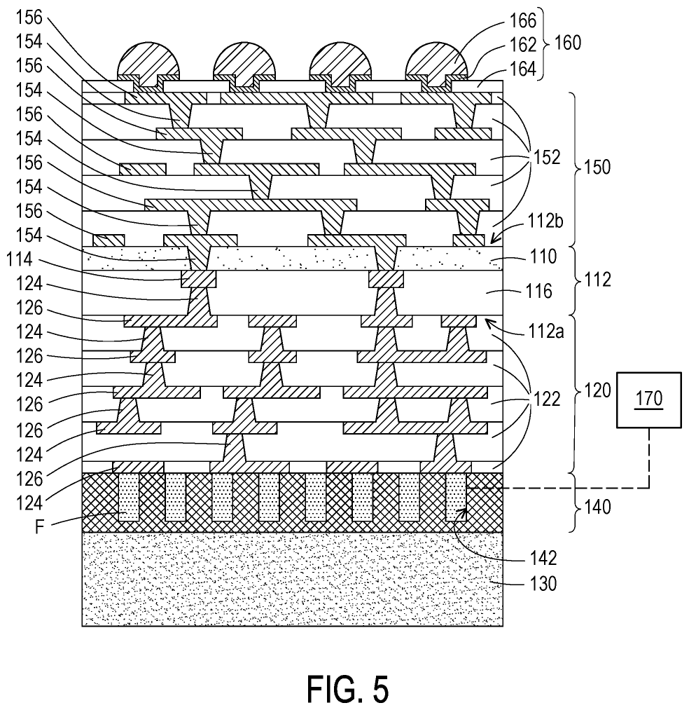

Referring to FIG. 1C, in some embodiments, after bonding, the bonding layer 140 is disposed between the routing structure 120 and the substrate 130. For example, the bonding layer 140 is in direct contact with the topmost dielectric layer 122, the topmost conductive vias 124 and/or the topmost conductive lines 126 of the routing structure 120. Similarly, the bonding layer 140 is in direct contact with the substrate 130, for example. In some embodiments, the microchannels 142 are configured to withstand the fluid flowing therethrough. Thus, a dimension (depth, width or the like) of the microchannels 142 and a thickness and/or a material of the bonding layer 140 may be designed for this purpose. In some embodiments, the microchannels 142 penetrate through the bonding layer 140, and thus the microchannels 142 are exposed to the routing structure 120 and the substrate 130. In such embodiments, first surfaces (e.g., bottom surfaces) of the microchannels 142 are substantially coplanar with a first surface (e.g., bottom surface) of the bonding layer 140, and second surfaces (e.g., top surfaces) opposite to the first surfaces of the microchannels 142 are substantially coplanar with second surface (e.g., top surface) opposite to the first surface of the bonding layer 140. The first surfaces (e.g., bottom surfaces) of the microchannels 142 are further substantially coplanar with surfaces (e.g., top surfaces) of the routing structure 120, and the second surfaces (e.g., top surfaces) of the microchannels 142 are further substantially coplanar with surfaces (e.g., bottom surfaces) of the substrate 130. However, the disclosure is not limited thereto. In alternative embodiments, as shown in FIG. 5, the microchannels 142 do not penetrate through the bonding layer 140, and the microchannels 142 are exposed to the routing structure 120 without being exposed to the substrate 130. In such embodiments, a depth of the microchannels 142 is smaller than a thickness of the bonding layer 140. First surfaces (e.g., bottom surfaces) of the microchannels 142 are higher than a first surface (e.g., bottom surface) of the bonding layer 140, and second surfaces (e.g., top surfaces) opposite to the first surfaces of the microchannels 142 are substantially coplanar with a second surface (e.g., top surface) opposite to the first surface of the bonding layer 140. The first surfaces (e.g., bottom surfaces) of the microchannels 142 may be disposed between the first and second surfaces (e.g., bottom and top surfaces) of the bonding layer 140.

In some embodiments, as shown in FIG. 3A to FIG. 3C or FIG. 4A to FIG. 4B, the bonding layer 140 are first formed over the substrate 130, and thus the formation of the microchannels 142 is performed over the substrate 130. However, the disclosure is not limited thereto. In alternative embodiments, the bonding layer 140 may be first formed over the routing structure 120, and the formation of the microchannels 142 is performed over the routing structure 120. In such embodiments, the substrate 130 is bonded to the routing structure 120 after the microchannels 142 of the bonding layer 140 are formed over the routing structure 120. In alternative embodiments, a first bonding layer is formed on the substrate 130, and a second bonding layer is formed on the routing structure 120, and then the substrate 130 and the routing structure 120 are bonded by bonding the first bonding layer and the second bonding layer. In such embodiments, at least one of the first and second bonding layers is formed with the microchannels (e.g., microchannels 142) therein.

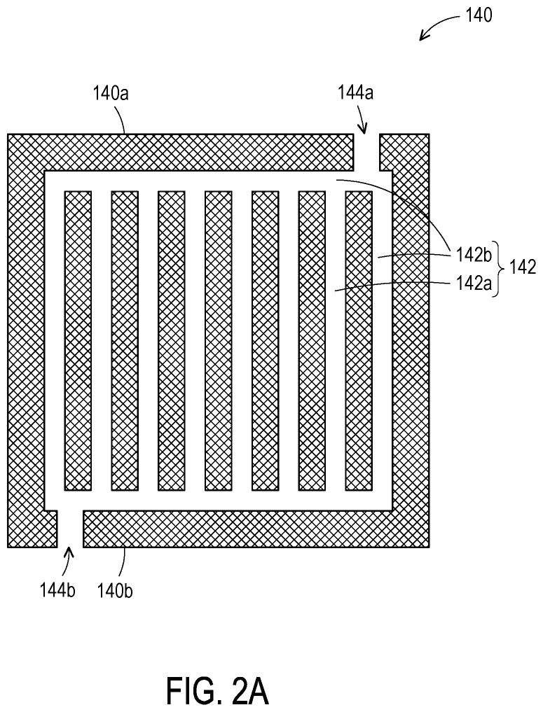

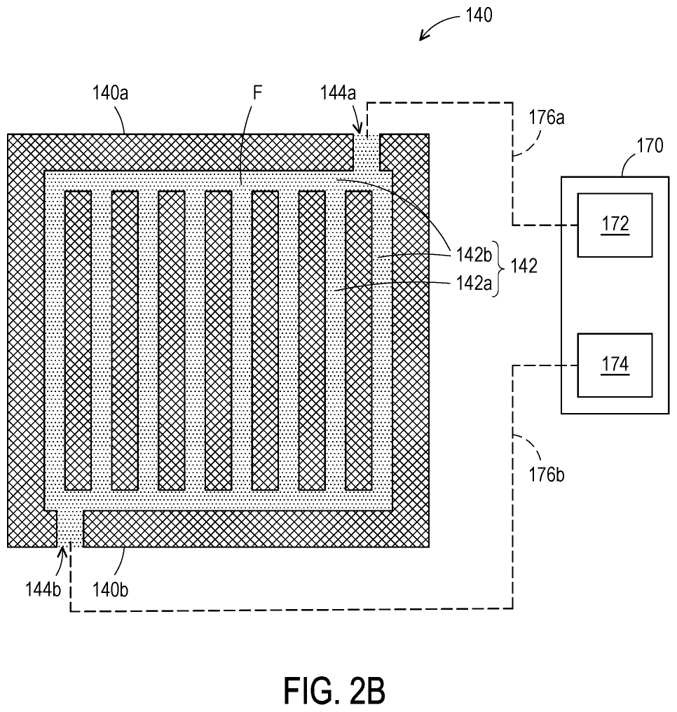

As shown in FIG. 2A, the microchannels 142 include a plurality of microchannels 142a and at least one microchannel 142b connecting the microchannels 142a. For example, the microchannel 142a extends along a first direction (e.g., y direction) and between a first sidewall 140a and a second sidewall 140b opposite to the first sidewall 140a of the bonding layer 140. The microchannels 142a may be arranged along a second direction (e.g., x direction) perpendicular to the first direction, and the microchannels 142a may be parallel to each other. The microchannel 142b extends along both the first direction (e.g., y direction) and the second direction (e.g., x direction), to surround and connect the microchannel 142a, for example. A width of the microchannel 142 along the second direction (e.g., x direction) may be in a range of 1 μm to 3 μm, and a depth of the microchannel 142 along a third direction (e.g., z direction) perpendicular to both first and second directions may be in a range of 1 μm to 3 μm. In some embodiments, a width of the microchannels 142a, 142b is substantially the same and a spacing between the microchannels 142a is also substantially the same. However, the disclosure is not limited thereto. The width and/or the spacing of the microchannels 142 may be different. For example, the width of the microchannel 142b connecting the microchannels 142a is larger than the width of the microchannels 142a. In addition, the microchannels 142 may individually have or cooperatively form any suitable shape such as net shape and spiral shape, and have any suitable arrangements and/or configurations.

In some embodiments, the microchannels 142 have at least one fluid inlet 144a and at least one fluid outlet 144b. For example, the fluid inlet 144a and the fluid outlet 144b are both at the outermost microchannel 142b. The fluid inlet 144a and the fluid outlet 144b are configured to connect with a fluid introduction element (not shown).

Referring to FIG. 1D, after the substrate 130 is bonded to the routing structure 120, the structure of FIG. 1C is flipped such that the side (e.g., backside) 112b of the device layer 112 faces upwards. Then, the substrate 110 is thinned down from a side distal from the substrate 130, such that a majority portion of the substrate 110 is removed. The thinning process may include a mechanical grinding process and/or a chemical thinning process. A substantial amount of the substrate 110 may be first removed during a mechanical grinding process. Afterwards, a chemical thinning process may apply an etching chemical to the backside of the substrate 110 to further thin down the substrate 110. In some embodiments, a portion of the substrate 110 is remained since the device layer 112 includes the portion of the substrate 110. However, the disclosure is not limited thereto. In alternative embodiments in which there is no component of the device layer in the substrate 110, the substrate 110 may be entirely removed.

Referring to FIG. 1E, a routing structure 150 is formed over the device layer 112, to electrically connect to the device layer 112. The routing structure 150 is formed on the side 112b (e.g., a backside) of the device layer 112, and the routing structure 150 may be also referred to as a backside multilayer interconnect (FMLI) structure. In some embodiments, the routing structure 150 includes a plurality of dielectric layers 152 and a plurality of conductive features (e.g., conductive vias 154, conductive lines 156 and/or contacts) in the dielectric layers 152. The conductive vias 154 and the conductive lines 156 may include a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), a metal three interconnect layer (M3 level), and all the way to a via x interconnect layer (Vx level), and a metal x interconnect layer (Mx level), in which x represents an integer (e.g., from 2 to 10).

Each of the V0 level, M0 level, V1 level, M1 level, V2 Level, M2 level, V3 level, M3 level, . . . . Vx level, and Mx level may be referred to as a metal level. The conductive lines 156 formed at the M0 level may be referred to as M0 metal lines. Similarly, conductive via or conductive lines formed at the V1 level, M1 level, V2 level, M2 level, V3 level, M3 level, . . . . Vx level, and Mx level may be referred to as V1 vias, M1 metal lines, V2 vias, M2 metal lines, V3 vias, M3 metal lines, . . . . Vx vias, Mx metal lines, respectively. In some embodiments, the conductive features at a same level of the routing structure 150, such as M0 level, are formed simultaneously. In some embodiments, conductive features at a same level of the routing structure 150 have top surfaces that are substantially planar with one another and/or bottom surfaces that are substantially planar with one another. In some embodiments, the conductive via 154 has an inclined sidewall, and a width of the conductive via 154 of the routing structure 150 decreases as the conductive via 154 becomes closer to the device layer 112. However, the disclosure is not limited thereto. The conductive via 154 may have a vertical sidewall or substantially vertical sidewall. In some embodiments, the conductive via 154 and/or the conductive line 156 are in contact with the underlying conductive features such as the conductive via 154 and/or the conductive line 156 in the routing structure 150 and/or conductive features (such as gate structures and/or source/drain features) in the devices 114. The conductive features may be formed by electroplating, deposition, the like or a combination thereof.

The dielectric layer 152 may be also referred to as an interlayer dielectric (ILD) layer. The dielectric layers 152 of the routing structure 150 may be collectively referred to as a dielectric structure. In some embodiments, the dielectric layer 152 include silicon oxide, TEOS formed oxide, undoped silicate glass, or doped silicate glass such as BPSG, FSG, PSG, BSG, and/or other suitable dielectric materials. In some embodiments, the dielectric layer 152 is deposited by CVD, PECVD, PVD, spin coating, the like, or a combination thereof. An etch stop layer (ESL) may be further disposed below the dielectric layer 152, respectively. The ESL may include a dielectric material, such as, silicon nitride, silicon oxide, silicon oxynitride, or the like, having a different etch rate than the material of the overlying dielectric layer 152.

A contact layer 160 is formed over the routing structure 150. The contact layer 160 may include contacts 162 arranged in a desired pattern. The contacts 162 may facilitate electrical connection of the circuitry in the device layer 112 to external circuitry and thus may be referred to as external contacts. In some embodiments, the contacts 162 are under-bump metallization (UBM) structures. In some embodiments, the contacts 162 are redistribution layer (RDL) structures. The contacts 162 may be in physical and electrical contact with the outermost conductive features (e.g., conductive vias 154, conductive lines 156 and/or contacts) of the routing structure 150. In some embodiments, the contact layer 160 includes at least one passivation layer, such as a passivation layer 164. In such embodiments, the contacts 162 are disposed in the passivation layer 164. The passivation layer 164 may include a material that is different than a dielectric material of the ILD layers in the dielectric structure of the routing structure 150. In some embodiments, the passivation layer includes polyimide, undoped silicate glass (USG), silicon oxide, silicon nitride, other suitable passivation material, or combinations thereof. In some embodiments, a dielectric constant of a dielectric material of the passivation layer is greater than a dielectric constant of the ILD layers in the routing structure 150. The passivation layer 164 may have a multilayer structure having multiple dielectric materials. For example, the passivation layer 164 can include a silicon nitride layer and a USG layer. In some embodiments, connectors 166 such as solder balls are formed to electrically connect to the contacts 162. In alternative embodiments (not shown), a through-substrate via (TSV) is formed to extend through the dielectric structure of the routing structure 150, the device layer 112 and the dielectric structure of the routing structure 120 and partially through the substrate 130.

Referring to FIG. 1F and FIG. 2B, a fluid introduction element 170 is attached to the formed semiconductor device. In some embodiments, the fluid introduction element 170 is configured to flow a fluid F into the microchannels 142 of the bonding layer 140. The fluid introduction element 170 may include a fluid supply source 172 and a waste fluid collector 174. The fluid supply source 172 may be connected to the fluid inlet 144a of the bonding layer 140 through a pipe 176a, and the waste fluid collector 174 may be connected to the fluid outlet 144b of the bonding layer 140 through a pipe 176b. In some embodiments, the fluid introduction element 170 includes a driver such as a bump to introduce the fluid F into the fluid inlet 144a of the bonding layer 140 from the fluid supply source 172, and drain the fluid F from the fluid outlet 144b of the bonding layer 140 into the waste fluid collector 174. In some embodiments, the bonding layer 140 having the fluid F flowing in the microchannels 142 is also referred to as a microfluidic device.

In some embodiments, the fluid F is a cooling material such as a dielectric fluid. The dielectric fluid has a low viscosity less than 5 mPa·s, for example. In some embodiments, the fluid F is perfluorinated carbon fluid. In alternative embodiments, the fluid F may be water, alcohol, gas, aromatics such as diethyl benzene (DEB) or dibenzyl toluene or any suitable fluid that does not react with the material of the bonding layer 140, the substrate 130 and the routing structure 120. In alternative embodiments, the fluid introduction element 170 may further include or connect to a cooling system, and thus the fluid supply source 172 may be maintained at a desired temperature. In alternative embodiments, the waste fluid collector 174 may be recycled to the fluid supply source 172 after treatment or cooling. In alternative embodiments, a thermal sensor may be disposed in a suitable location of the semiconductor device such as the device layer 112, and the thermal sensor may measure the temperature of the device layer 112, and provides thermal information (e.g., feedback) for the fluid introduction element 170. The fluid introduction element 170 may receive the thermal information and determine to perform heat dissipation process or not and/or determine the sort, the amount and/or the flow rate of the fluid F. In alternative embodiments as shown in FIG. 1E, the fluid F and the fluid introduction element 170 are omitted, and thus the microchannels 142 of the bonding layer 140 are filled with air rather than the fluid F. In alternative embodiments, in order to strengthen the rigidity and/or heat dissipation of the semiconductor device, supporting pillars and/or thermal pillars (e.g., metal pillars) may be formed in the bonding layer. The openings for the supporting pillars and/or thermal pillars may be formed simultaneously with the microchannels 142 by a same process such as printing process or patterning process.

In some embodiments, the fluid introduction element 170 introduces the fluid F into the microchannels 142 of the bonding layer 140, and thus the fluid F may flow in the bonding layer 140 between the substrate 130 and the routing structure 120. In some embodiments in which the microchannels 142 penetrate through the bonding layer 140, the fluid F is in direct contact with the outermost surfaces of the substrate 130 and the routing structure 120. In some embodiments in which the microchannels 142 do not penetrate through the bonding layer 140 as shown in FIG. 5, the fluid F is in direct to the outermost surface of the routing structure 120 and not in direct contact with the substrate 130. The semiconductor device may be a CFET device, a memory device or the like, and the semiconductor device adopts the routing structures (e.g., frontside routing structure and backside routing structure) on opposite surfaces (e.g., frontside and backside) of the device layer. In some embodiments, the routing structures is also referred to as a dual-side super power rail (SPR).

In some embodiments, since the fluid F continuously flows in the microchannels 142 of the bonding layer 140 between the substrate 130 and the routing structure 120, the heat generated in the semiconductor device (e.g., heat generated in the device layer 112) may be efficiently and actively dissipated. For example, the heat dissipation path is formed between the device layer 112, the conductive vias 124 and the conductive lines 126 of the routing structure 120 and the bonding layer 140, and thus the semiconductor device (e.g., CFET) may be cooled. Accordingly, the performance and yield of the semiconductor device (e.g., CFET) may be improved. In some embodiments, if needed, the heat in other layers such as the routing structure 150 and the contact layer 160 may be also dissipated from the bonding layer 140. Furthermore, since the microchannels 142 are formed in the bonding layer 140 through suitable semiconductor process, the formation of the microfluidic device (e.g., bonding layer 140 with microchannels 142) may be easily integrated into the formation of the semiconductor device.

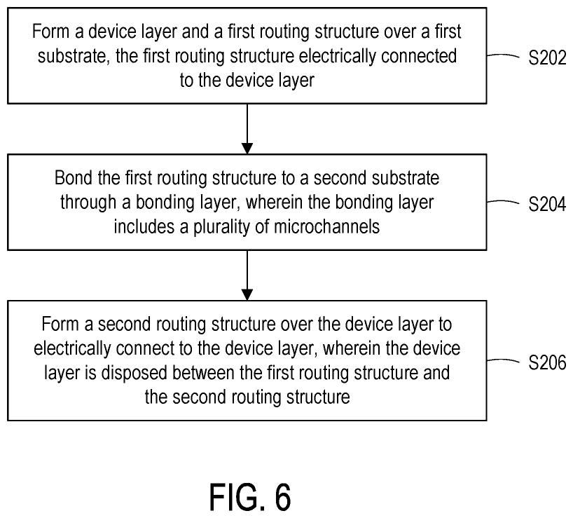

FIG. 6 illustrates a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S202, a device layer and a first routing structure are formed over a first substrate, the first routing structure is electrically connected to the device layer. FIG. 1A, FIG. 1B and FIG. 5 illustrate varying views corresponding to some embodiments of act S202.

At act S204, the first routing structure is bonded to a second substrate through a bonding layer, wherein the bonding layer includes a plurality of microchannels. FIG. 1C, FIG. 2A, FIG. 3A to FIG. 3C, FIG. 4A to FIG. 4B and FIG. 5 illustrate varying views corresponding to some embodiments of act S204.

At act S206, a second routing structure is formed over the device layer to electrically connect to the device layer, wherein the device layer is disposed between the first routing structure and the second routing structure. FIG. 1D to FIG. 1F and FIG. 5 illustrate views corresponding to some embodiments of act S206.

According to some embodiments of the disclosure, a semiconductor device includes a substrate, a routing structure, a device layer and a bonding layer. The routing structure is disposed over the substrate, and includes a plurality of dielectric layer and a plurality of conductive features. The device layer is disposed over the routing structure. The bonding layer is disposed between the substrate and the routing structure, wherein the bonding layer includes a plurality of microchannels.

According to some embodiments of the disclosure, a semiconductor device includes a substrate, a device layer, a first routing structure, a second routing structure, a bonding layer and a fluid introduction element. The device layer includes a device. The first routing structure is disposed at a first surface of the device layer and between the substrate and the device layer. The second routing structure is disposed at a second surface opposite to the first surface of the device layer. The bonding layer is disposed between the substrate and the first routing structure, wherein the bonding layer comprises a plurality of microchannels. The fluid introduction element is configured to flow a fluid into the microchannels of the bonding layer.

According to some embodiments of the disclosure, a method of forming a semiconductor device includes following steps. A device layer and a first routing structure are formed over a first substrate, and the first routing structure is electrically connected to the device layer. The first routing structure is bonded to a second substrate through a bonding layer, wherein the bonding layer comprises a plurality of microchannels. A second routing structure is formed over the device layer to electrically connect to the device layer, wherein the device layer is disposed between the first routing structure and the second routing structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a routing structure over the substrate, comprising a plurality of dielectric layer and a plurality of conductive features;
a device layer over the routing structure; and
a bonding layer between the substrate and the routing structure, wherein the bonding layer comprises a plurality of microchannels.

2. The semiconductor device of claim 1, wherein the bonding layer is in direct contact with the substrate and the routing structure.

3. The semiconductor device of claim 1, wherein the microchannels penetrate through the bonding layer.

4. The semiconductor device of claim 1, wherein at least one of the dielectric layers comprises a low-k material.

5. The semiconductor device of claim 1, wherein a material of the bonding layer is silicon oxide.

6. A semiconductor device, comprising:
a substrate;
a device layer comprising a device;
a first routing structure at a first surface of the device layer and between the substrate and the device layer;
a second routing structure at a second surface opposite to the first surface of the device layer;
a bonding layer between the substrate and the first routing structure, wherein the bonding layer comprises a plurality of microchannels; and
a fluid introduction element, configured to flow a fluid into the microchannels of the bonding layer.

7. The semiconductor device of claim 6, wherein the bonding layer comprises a fluid inlet and a fluid outlet respectively connected to the fluid introduction element.

8. The semiconductor device of claim 6, wherein the fluid is a dielectric fluid.

9. The semiconductor device of claim 6, wherein the fluid is a perfluorinated carbon fluid.

10. The semiconductor device of claim 6, wherein the microchannels comprise a plurality of first microchannels and a second microchannel connecting the first microchannels.

11. The semiconductor device of claim 10, wherein the first microchannels are parallel to each other, and the second microchannel surrounds the first microchannels.

12. The semiconductor device of claim 6, wherein a surface of the microchannels is disposed between opposite surfaces of the bonding layer.

13. The semiconductor device of claim 6, wherein a surface of the microchannels is substantially coplanar with at least one of a surface of the substrate and a surface of the first routing structure facing the surface of the substrate.

14. The semiconductor device of claim 6, wherein a first surface of the microchannels is substantially coplanar with a surface of the substrate, and a second surface opposite to the first surface of the microchannels is substantially coplanar with a surface of the first routing structure facing the surface of the substrate.

15. A method of forming a semiconductor device, comprising:
forming a device layer and a first routing structure over a first substrate, the first routing structure electrically connected to the device layer;
bonding the first routing structure to a second substrate through a bonding layer, wherein the bonding layer comprises a plurality of microchannels; and
forming a second routing structure over the device layer to electrically connect to the device layer, wherein the device layer is disposed between the first routing structure and the second routing structure.

16. The method of claim 15, wherein the microchannels are formed in the bonding layer before bonding the first routing structure to the second substrate.

17. The method of claim 15, wherein a method of forming the microchannels comprises:
printing the bonding layer, to form the microchannels; and
curing the bonding layer.

18. The method of claim 15, wherein a method of forming the microchannels comprises:
forming a photoresist on the bonding layer;
patterning the photoresist, to form a pattern of microchannels;
by using the patterned photoresist as a mask, patterning the bonding layer to form the microchannels; and
removing the patterned photoresist.

19. The method of claim 15, wherein the microchannels are formed to penetrate through the bonding layer.

20. The method of claim 15, further comprising removing a portion of the first substrate before forming the second routing structure.
